(19) United States
(12) Patent Application Publication
(10) Pub. No.: US 2023/0330807 A1
(43) Pub. Date: Oct. 19, 2023

(54) SPINDLE UNIT

(71) Applicant: DISCO CORPORATION, Tokyo (JP)

(72) Inventor: Yasushi KATAGIRI, Tokyo (JP)

(21) Appl. No.: 18/194,785

(22) Filed: Apr. 3, 2023

(30) Foreign Application Priority Data
Apr. 19, 2022 (JP) 2022-068611

(51) Int. Cl. B24B 55/04; B24B 41/04

(52) U.S. Cl. CPC B24B 41/04; B24B 55/04

(57) ABSTRACT

A region of a side surface of a tip part of a spindle, the region being opposed to an inside surface of a cover with a gap therebetween, is formed with a groove going round the spindle one time. At a location where the groove is formed, the sectional area of the gap between the tip part and the cover is enlarged. Hence, the gap between the tip part of the spindle and the cover can be expressed as a space (passage) in which a small sectional area and a space (expansion chamber) having a large sectional area are alternately disposed. If processing liquid containing processing swarf enters into the gap, the processing liquid is not likely to enter into the passage. Deposition of the swarf onto the tip part of the spindle is restrained, making it possible to reduce the frequency of cleaning of the tip part.

### BACKGROUND OF THE INVENTION

### Field of the Invention

The present invention relates to a spindle unit.

### Description of the Related Art

Chips of such devices as integrated circuits (ICs) are indispensable constituent elements in various electronic apparatuses such as mobile phones and personal computers. Such chips are manufactured, for example, in the following sequence.

First, photolithography or the like is carried out to form a multiplicity of elements on a front surface of a workpiece such as a wafer, thereby forming a plurality of devices. Next, the back surface side of the workpiece is ground to thin the workpiece. Subsequently, the workpiece is cut along boundaries of the plurality of devices, to divide the workpiece into a plurality of chips.

A processing apparatus such as a grinding apparatus for grinding the workpiece or a cutting apparatus for cutting the workpiece is typically provided with a spindle unit including a spindle having a tip part to which a mount for mounting a processing tool is connected and a casing which surrounds at least a part other than the tip part of the spindle and which is formed with an air jet port for jetting air toward the spindle in order to form an air bearing.

Specifically, in the grinding apparatus, an annular grinding wheel provided with a plurality of grindstones dispersed in an annular pattern is mounted to the mount. In a state in which air is jetted from the air jet port of the casing toward the spindle to thereby form an air bearing between them, the plurality of grindstones are brought into contact with the workpiece while the grinding wheel is rotated together with the spindle, whereby the workpiece is ground.

In addition, in the cutting apparatus, an annular cutting blade in which abrasive grains are dispersed is mounted to the mount. In a state in which air is jetted from the air jet port of the casing toward the spindle to thereby form an air bearing between them, the cutting blade is brought into contact with the workpiece while the cutting blade is rotated together with the spindle, whereby the workpiece is cut.

Further, in these processing apparatuses, the workpiece is processed while processing liquid is supplied to a contact point (processing point) between the workpiece and the processing tool in order to wash away processing swarf generated attendant on the processing of the workpiece. It is to be noted that, since such processing is conducted in a state in which the processing tool is rotated at high speed together with the spindle, the processing liquid containing the processing swarf is scattered in a mist form.

Here, if the processing liquid containing the processing swarf is deposited on a region in the vicinity of the air jet port formed in the casing, it may become difficult to form the air bearing in the spindle unit. In the spindle unit, therefore, it is a general practice to provide a cover surrounding the tip part of the spindle in order to prevent the deposition of the processing liquid on this region.

Note that this cover surrounds the tip part of the spindle with a gap therebetween such that the air jetted from the air jet port formed in the casing is exhausted and that the rotation of the spindle is not hindered. Hence, when the workpiece is processed by these processing apparatuses, the processing liquid containing the processing swarf may enter into the gap and may be deposited on a side surface of the tip part of the spindle.

When the processing liquid deposited on the side surface of the tip part of the spindle is dried and the processing swarf is secured to the side surface, normal rotation of the spindle may be hindered. For example, if the gap between the tip part of the spindle and the cover is filled up with the processing swarf, exhausting of the air jetted from the air jet port of the casing would be hindered. In this case, a rotational axis of the spindle may be inclined, and the spindle may make contact with the casing and/or the cover.

In consideration of this point, a spindle unit in which a tip part of a spindle is surrounded by a cover capable of being disassembled into two parts has been proposed (refer to, for example, Japanese Patent Laid-open No. 2017-222003). In this spindle unit, after the cover is divided into the two parts to expose the tip part of the spindle, the tip part can be cleaned.

### SUMMARY OF THE INVENTION

However, it is troublesome to disassemble the cover into two parts prior to cleaning of the tip part of the spindle and to assemble the cover again after cleaning thereof, and the burden on the operator is heavy. In consideration of this point, it is an object of the present invention to provide a spindle unit in which the deposition of processing liquid containing the processing swarf onto a tip part of the spindle can be restrained and the frequency of cleaning of the tip part can be reduced.

In accordance with an aspect of the present invention, there is provided s spindle unit including a spindle having a tip part to which a mount for mounting a processing tool is connected, a casing that surrounds at least a part other than the tip part of the spindle and is formed with an air jet port for jetting air toward the spindle in order to form an air bearing, and a cover mounted to the casing in such a manner as to surround the tip part of the spindle with a gap therebetween. A region of a side surface of the tip part of the spindle, the region being opposed to an inside surface of the cover with the gap therebetween, is formed with at least one groove in such a manner as to go round the spindle one time along a circumferential direction of the spindle.

Further, it is preferable that, in the one aspect of the present invention, the at least one groove be a plurality of grooves.

In accordance with another aspect of the present invention, there is provided a spindle unit including a spindle having a tip part to which a mount for mounting a processing tool is connected, a casing that surrounds at least a part other than the tip part of the spindle and is formed with an air jet port for jetting air toward the spindle in order to form an air bearing, and a cover mounted to the casing in such a manner as to surround the tip part of the spindle with a gap therebetween. A region of a side surface of the tip part of the spindle, the region being opposed to an inside surface of the cover with the gap therebetween, is formed with a spiral groove in such a manner as to go round the spindle at least one time along a direction inclined relative to a circumferential direction of the spindle. The spindle is rotated such that fluid retained inside the spiral groove is carried toward a mount side.

Further, in the other aspect of the present invention, it is preferable that the spiral groove be formed in such a manner as to go round the spindle at least two times.

In the spindle unit of the present invention, the groove going round the spindle one time is formed in the region of the side surface of the tip part of the spindle, the region being opposed to the inside surface of the cover with the gap therebetween. In the location where the groove is formed, the sectional area of the gap between the tip part of the spindle and the cover is enlarged.

Hence, the gap between the tip part of the spindle and the cover can be expressed as a space in which a space (passage) smaller in sectional area and a space (expansion chamber) larger in sectional area are alternately disposed. Here, when fluid moves from the space larger in sectional area into the space smaller in sectional area, a large pressure loss is generated.

Therefore, even in the case where the processing liquid containing the processing swarf enters into the gap between the tip part of the spindle and the cover, the processing liquid is not liable to enter into the passage provided in the depth of the expansion chamber. As a result, in the spindle unit of the present invention, deposition of the processing liquid containing the processing swarf onto the tip part of the spindle is restrained, and the frequency of cleaning of the tip part can be reduced.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view schematically depicting a grinding apparatus by way of example;

FIG. 2 is a partly sectional side view schematically depicting, by way of example, a spindle unit included in the grinding apparatus;

FIG. 3 is a partial enlarged diagram depicting a gap between a tip part of the spindle by way of example and a cover depicted by way of example depicted in FIG. 2; and

FIG. 4 is a front view schematically depicting a tip part of another spindle by way of example.

### DETAILED DESCRIPTION OF THE PREFERRED EMBODIMENT

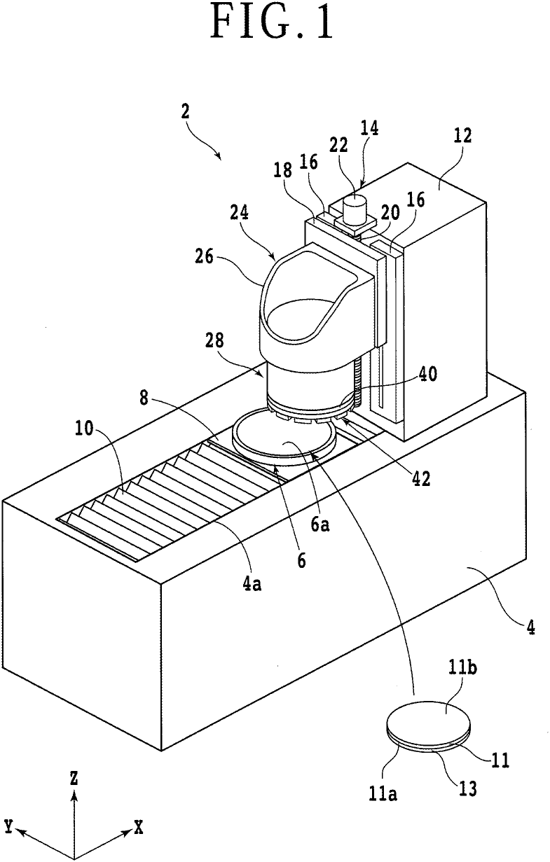

An embodiment of the present invention will be described with reference to the attached drawings. FIG. 1 is a perspective view schematically depicting a grinding apparatus by way of example. Note that an X-axis direction (front-rear direction) and a Y-axis direction (left-right direction) are directions orthogonal to each other on a horizontal plane, and a Z-axis direction (upper-lower direction) is a direction (vertical direction) orthogonal to the X-axis direction and the Y-axis direction.

The grinding apparatus, denoted by 2, depicted in FIG. 1 has a base 4 that supports each of constituent elements. An upper surface of the base 4 is formed with a rectangular parallelepiped groove 4a extending along the X-axis direction. On the upper side of the groove 4a, a chuck table 6 is provided. In addition, inside the groove 4a, there are provided an X-axis direction moving mechanism (not illustrated) connected to the chuck table 6, a rotational drive source (not illustrated), and a suction source (not illustrated).

The X-axis direction moving mechanism includes, for example, a motor, a ball screw, and the like, and moves the chuck table 6 along the X-axis direction. Besides, the rotational drive source includes, for example, a motor, a pulley, and the like, and rotates the chuck table 6 with a straight line passing through the center of an upper surface (holding surface) of the chuck table 6 as a rotational axis.

In addition, the suction source includes an ejector or the like, and causes a suction force to act on a space in the vicinity of the holding surface of the chuck table 6. Hence, when the suction source is operated in a state in which a workpiece 11 is placed on the holding surface of the chuck table 6, the workpiece 11 is held by the chuck table 6.

The workpiece 11 is, for example, a wafer which is formed of a semiconductor material such as silicon, and is formed with a plurality of devices on a front surface 11a side thereof. Besides, to the front surface 11a of the workpiece 11, for example, a protective tape 13 which is formed of resin and which prevents breakage of the devices when a back surface 11b side of the workpiece 11 is ground is stuck.

Further, in the periphery of the chuck table 6, a rectangular parallelepiped table cover 8 surrounding the chuck table 6 such that the holding surface, denoted by 6a, of the chuck table 6 is exposed is provided. The width (the length along the Y-axis direction) of the table cover 8 is substantially equal to the width of the groove 4a formed in the upper surface of the base 4. Besides, on the front and rear sides of the table cover 8, dust-proof and droplet-proof covers 10 contractible and extendable along the X-axis direction are provided.

Besides, in a region of the upper surface of the base 4, the region being located on the rear side of the groove 4a, a quadrangular prism-shaped support structure 12 is provided. On the front surface side of the support structure 12, a Z-axis direction moving mechanism 14 is provided. The Z-axis direction moving mechanism 14 has a pair of guide rails 16 that each extend along the Z-axis direction. Besides, on the front sides of the respective ones of the pair of guide rails 16, sliders (not illustrated) are provided in the manner of being slidable along the Z-axis direction.

In addition, front end parts of the sliders are fixed to the rear surface side of a rectangular parallelepiped Z-axis moving plate 18. Further, between the pair of guide rails 16, there is disposed a screw shaft 20 extending along the Z-axis direction. A pulse motor 22 for rotating the screw shaft 20 is connected to an upper end part of the screw shaft 20.

Besides, on an outer circumferential surface of the screw shaft 20 where a screw thread is formed, a nut (not illustrated) for accommodating balls circulated according to the rotation of the screw shaft 20 is provided, to constitute a ball screw. In addition, this nut is fixed to the rear surface side of the Z-axis moving plate 18. Hence, when the screw shaft 20 is rotated by the pulse motor 22, the Z-axis moving plate 18 is moved along the Z-axis direction together with the nut.

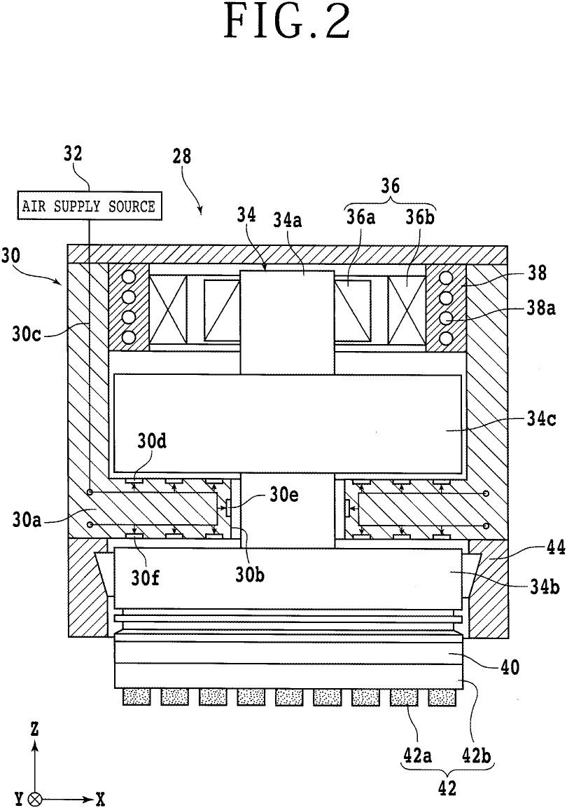

Further, a grinding unit 24 is provided on the front side of the Z-axis moving plate 18. The grinding unit 24 has a cylindrical holding member 26 fixed to a front surface of the Z-axis moving plate 18. The holding member 26 holds a spindle unit 28. FIG. 2 is a partly sectional side view that schematically depicts the spindle unit 28. Note that, in FIG. 2, one of constituent elements of the spindle unit 28 is depicted as a block.

The spindle unit 28 has a cylindrical casing 30. A bottom wall 30a of the casing 30 is formed in its center with a cylindrical through-hole 30b. In addition, the bottom wall 30a of the casing 30 is formed with an air supply passage 30c communicating with an air supply source 32. The air supply passage 30c communicates with a plurality of air jet ports 30d opening in an upper surface of the bottom wall 30a, a plurality of air jet ports 30e opening in an inside surface of the bottom wall 30a, and a plurality of air jet ports 30f opening in a lower surface of the bottom wall 30a.

In addition, the casing 30 surrounds at least a part other than a tip part of a spindle 34. The spindle 34 has a cylindrical shaft section 34a extending along the Z-axis direction and a pair of flange sections 34b and 34c each provided in such a manner as to project from the shaft section 34a along a radial direction of the shaft section 34a. Specifically, the flange section 34b is provided at a tip part (lower end part) of the shaft section 34a, and the flange section 34c is provided between a base end part (upper end part) and the tip part (lower end part) of the shaft section 34a.

Further, the diameter of each of the pair of flange sections 34b and 34c is slightly smaller than the inside diameter of the casing 30. Besides, the spacing between the pair of flange sections 34b and 34c is slightly larger than the thickness of the bottom wall 30a of the casing 30. A part of the shaft section 34a of the spindle 34, the part being located between the pair of flange sections 34b and 34c, is passed through the through-hole 30b of the casing 30.

In addition, a motor 36 is provided in the surrounding of a base end part of the spindle 34, specifically, a base end part of the shaft section 34a. The motor 36 has a rotor 36a fixed to the base end part of the spindle 34 and a stator 36b surrounding the rotor 36a with a gap therebetween. Besides, the stator 36b is fixed to the casing 30 through a cooling jacket 38. The cooling jacket 38 is formed with a cooling water passage 38a which is supplied with cooling water for cooling the motor 36.

In addition, a disk-shaped mount 40 having a diameter substantially equal to the outside diameter of the flange section 34b is connected to a tip part, specifically, the flange section 34b of the spindle 34. A grinding wheel (processing tool) 42 having a diameter substantially equal to the diameter of the mount 40 is mounted to the mount 40. Further, a cylindrical cover 44 formed of such resin as polyvinyl chloride, for example, is provided in the periphery of the tip part of the spindle 34. The cover 44 is mounted to the casing 30 in such a manner as to surround the tip part of the spindle 34 with a gap therebetween.

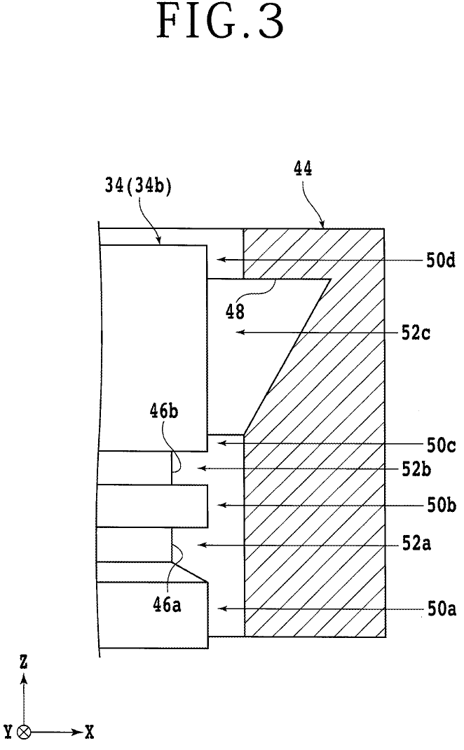

FIG. 3 is a partial enlarged diagram depicting a gap between the tip part of the spindle 34 and the cover 44 depicted in FIG. 2. A region of a side surface of the tip part of the spindle 34, the region being opposed to an inside surface of the cover 44, is formed with two grooves 46a and 46b. Each of the two grooves 46a and 46b is formed in such a manner as to go round the spindle 34 one time along a circumferential direction of the spindle 34.

Besides, the sectional shape of the groove 46a is a trapezoid whose width becomes narrower as going nearer to a bottom surface of the groove 46a. Specifically, a side surface on the mount 40 side of the groove 46a is inclined relative to the circumferential direction of the spindle 34. For example, the angle defined by this side surface and a plane parallel to the X-axis direction and the Y-axis direction is 10° to 50°, typically 30°. In addition, a side surface on the casing 30 side of the groove 46a is substantially parallel to the circumferential direction of the spindle 34.

In addition, the sectional shape of the groove 46b is a rectangle having a substantially constant width. Specifically, each of a pair of side surfaces of the groove 46b is substantially parallel to the circumferential direction of the spindle 34. Further, the depths (the lengths along a direction orthogonal to the Z-axis direction) of the two grooves 46a and 46b may be the same or different. Similarly, the widths (the lengths along the Z-axis direction) of the respective bottom surfaces of the two grooves 46a and 46b may be the same or different.

Besides, an inside surface of the cover 44 is also formed with a groove 48. The groove 48 goes round the inside surface of the cover 44 one time, and is opposed to a region of the side surface of the tip part of the spindle 34, the region being located above the groove 46b. In addition, the sectional shape of the groove 48 is a right-angled triangle. Specifically, the groove 48 is configured by a side surface on the mount 40 side that is inclined relative to the circumferential direction of the spindle 34 and a side surface on the casing 30 side that is substantially parallel to the circumferential direction of the spindle 34.

Note that the sectional shape of the groove 46a may be a rectangle like that of the groove 46b, or may be a right-angled triangle like that of the groove 48. In addition, the sectional shape of the groove 46b may be a trapezoid like that of the groove 46a, or may be a right-angled triangle like that of the groove 48. Besides, the sectional shape of the groove 48 may be a trapezoid like that of the groove 46a, or may be a rectangle like that of the groove 46b.

At locations where the groove 46a, the groove 46b, or the groove 48 is formed, the sectional area (specifically, the area of a cross-section parallel to the X-axis direction and the Y-axis direction) of the gap between the tip part of the spindle 34 and the cover 44 is enlarged. Hence, the gap between the tip part of the spindle 34 and the cover 44 can be expressed as a space in which spaces (passages) 50a, 50b, 50c, and 50d smaller in sectional area and spaces (expansion chambers) 52a, 52b, and 52c larger in sectional area are alternately disposed from the mount 40 side.

Note that the widths (the lengths along a direction orthogonal to the Z-axis direction) of the passages 50a, 50b, 50c, and 50d are, for example, 0.1 to 2.0 mm. Besides, the widths (the spacings between the bottom surfaces of the grooves 46a and 46b and the inside surface of the cover 44) of the expansion chambers 52a and 52b are, for example, 2.0 to 5.0 mm. In addition, the maximum width of the expansion chamber 52c (the spacing between the side surface of the spindle 34 and the deepest location of the groove 48) is, for example, 2.0 to 5.0 mm.

In addition, the grinding wheel 42 depicted in FIGS. 1 and 2 has a plurality of grindstones 42a and a wheel base 42b having a lower surface on which the plurality of grindstones 42a are dispersedly disposed in an annular pattern. Note that the plurality of grindstones 42a have abrasive grains of diamond, cubic boron nitride (cBN), or the like dispersed in a bonding material such as a vitrified bond or a resin bond.

Besides, the wheel base 42b is formed of, for example, a metallic material such as stainless steel or aluminum. Further, in the vicinity of the grinding wheel 42, a processing liquid supply nozzle (not illustrated) for supplying liquid (processing liquid) such as pure water to a processing point during grinding of the workpiece 11 by the plurality of grindstones 42a is provided.

At the time of grinding the workpiece 11 in the above-described grinding apparatus 2, first, the suction source connected to the chuck table 6 is operated in a state in which the workpiece 11 is placed on the holding surface 6a of the chuck table 6 with the protective tape 13 therebetween. As a result, the workpiece 11 is held by the chuck table 6 in a state in which the back surface 11b of the workpiece 11 is exposed.

Next, the X-axis direction moving mechanism connected to the chuck table 6 is operated such that the locus of the plurality of grindstones 42a when the grinding wheel 42 is rotated together with the spindle 34 overlap with the center of the holding surface 6a of the chuck table 6.

Subsequently, air supplied from the air supply source 32 through the air supply passage 30c is jetted from the air jet ports 30d, 30e, and 30f of the casing 30 toward the spindle 34. As a result, an air bearing is formed between the casing 30 and the spindle 34. Note that the air jetted from the air jet ports 30d, 30e, and 30f is exhausted through, for example, a gap between the spindle 34 and the cover 44 to the exterior of the spindle unit 28.

Next, the rotational drive source connected to the chuck table 6 is operated in such a manner as to rotate the chuck table 6, and the motor 36 is operated in such a manner as to rotate the grinding wheel 42 together with the spindle 34.

Subsequently, the Z-axis direction moving mechanism 14 is operated in such a manner as to bring the plurality of grindstones 42a into contact with the workpiece 11. Specifically, the pulse motor 22 is operated in such a manner as to lower the Z-axis moving plate 18. Besides, processing liquid is supplied from the processing liquid supply nozzle to a contact interface of the plurality of grindstones 42a and the workpiece 11.

As a result, the back surface 11b side of the workpiece 11 is ground. In this instance, the processing liquid containing the processing swarf generated by the grinding is scattered in a mist form. Then, the thus scattered processing liquid enters into the gap between the tip part of the spindle 34 and the cover 44 in some cases.

Here, the grooves 46a and 46b going round the spindle 34 one time are formed in the region of the side surface of the tip part of the spindle 34, the region being opposed to the inside surface of the cover 44. In other words, the gap between the tip part of the spindle 34 and the cover 44 includes the passages 50a, 50b, and 50c and the expansion chambers 52a and 52b which are alternately disposed.

Hence, even in the case where the processing liquid containing processing swarf enters into the gap between the tip part of the spindle 34 and the cover 44, the processing liquid is not liable to enter into the passages 50b and 50c provided in the depth of the expansion chambers 52a and 52b. As a result, in the spindle unit 28, deposition of the processing liquid containing the processing swarf onto the tip part of the spindle 34 is restrained, and the frequency of cleaning of the tip part can be reduced.

Further, in the spindle unit 28, the groove 48 that goes round the inside surface of the cover 44 one time and is opposed to the region of the side surface of the tip part of the spindle 34, the region being located above the groove 46b, is formed in the cover 44. Hence, even in the case where the processing liquid enters into the passage 50c, deposition of the processing liquid onto the regions in the vicinity of the air jet ports 30d, 30e, and 30f formed in the bottom wall of the casing 300 can be restrained.

In addition, in the spindle unit 28, the processing liquid which has not been able to enter into the passage 50b is liable to be deposited on the bottom surface and/or side surfaces of the groove 46a, and the processing liquid which has not been able to enter into the passage 50c is liable to be deposited on a bottom surface and/or the side surfaces of the groove 46b. However, the processing liquid deposited on the bottom surfaces and/or the side surfaces of the grooves 46a and 46b is liable to be discharged from the grooves 46a and 46b by a centrifugal force acting attendantly on the rotation of the spindle 34.

Then, the processing liquid discharged from the grooves 46a and 46b is liable to be discharged to the exterior of the gap between the tip part of the spindle 34 and the cover 44 while flowing on the inside surface of the cover 44. In other words, in the spindle unit 28, even in the case where the processing liquid is deposited on the bottom surfaces and/or the side surfaces of the grooves 46a and 46b, the discharge of the processing liquid can be promoted.

Further, a side surface on the mount 40 side of the groove 46a is inclined relative to the circumferential direction of the spindle 34. Hence, the processing liquid deposited on the bottom surface and/or the side surfaces of the groove 46a is liable to flow along the side surface on the mount 40 side of the groove 46a by the centrifugal force acting attendantly on the rotation of the spindle 34.

Then, the processing liquid having flowed along the side surface on the mount 40 side of the groove 46a is liable to be discharged to the exterior of the gap between the tip part of the spindle 34 and the cover 44 by passing through the passage 50a. In other words, in the spindle unit 28, even in the case where the processing liquid is deposited on the bottom surface and/or the side surfaces of the groove 46a, the discharge of the processing liquid can be promoted.

Note that the contents of the above description is one mode of the present invention, and the contents of the present invention is not limited to the contents of the above description. For example, the spindle unit of the present invention is not limited to the spindle unit provided in the grinding apparatus 2, and may be a spindle unit provided in a cutting apparatus.

In addition, in the spindle unit of the present invention, the number of the grooves formed in the side surface of the tip part of the spindle 34 is not limited to two. For example, the number of the above grooves may be one, or may be three or more. It is to be noted, however, that from the viewpoint of preventing the entering of the processing liquid containing the processing swarf into the gap between the tip part of the spindle 34 and the cover 44, it is preferable that a plurality of grooves be formed in the side surface of the tip part of the spindle 34.

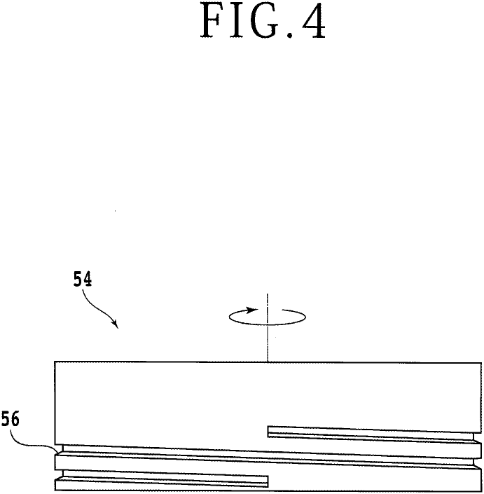

Besides, in the spindle unit of the present invention, a spiral groove may be formed in the side surface of the tip part of the spindle. FIG. 4 is a front view schematically depicting a tip part of a spindle that is formed with a spiral groove in the tip part, that is, a part corresponding to the flange section 34b depicted in FIGS. 2 and 3.

The spiral groove, denoted by 56, formed in a side surface of the tip part of the spindle, denoted by 54, is formed in such a manner as to go round the spindle 54 two times along a direction inclined relative to a circumferential direction of the spindle 54.

Besides, the sectional shape of the groove 56 is a trapezoid like that of the groove 46a depicted in FIG. 3. Note that the sectional shape of the groove 56 may be a rectangle like that of the groove 46b depicted in FIG. 3, or may be a right-angled triangle like that of the groove 48 depicted in FIG. 3.

Further, in a case where the spindle 54 is included in the spindle unit, it is preferable that, when the workpiece 11 is ground, the spindle 54 be rotated along a direction indicated by an arrow in FIG. 4. In this case, fluid retained inside the groove 56 is carried to the mount side. As a result, even in a case where the processing liquid is deposited on a bottom surface and/or side surfaces of the groove 56, the discharge of the processing liquid can be promoted.

Note that the number of times that the groove 56 extending round the spindle 54 goes around the spindle 54 is not limited to two. For example, the number of times that the groove 56 goes round the spindle 54 may be one, or may be three or more. It is to be noted, however, that from the viewpoint of preventing the entering of the processing liquid containing the processing swarf into the gap between the tip part of the spindle 54 and the cover, it is preferable that the spiral groove 56 be formed in such a manner as to go round the spindle 54 at least two times.

In addition, in the spindle unit of the present invention, the groove may not be formed in the inside surface of the cover 44. Besides, in the spindle unit of the present invention, a plurality of grooves may be formed in the inside surface of the cover 44.

Other than the above, structures, methods, and the like concerning the above-described embodiment can be appropriately modified in carrying out the invention insofar as the modifications do not depart from the scope of the object of the invention.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A spindle unit comprising:
a spindle having a tip part to which a mount for mounting a processing tool is connected;
a casing that surrounds at least a part other than the tip part of the spindle and is formed with an air jet port for jetting air toward the spindle in order to form an air bearing; and
a cover mounted to the casing in such a manner as to surround the tip part of the spindle with a gap therebetween,
wherein a region of a side surface of the tip part of the spindle, the region being opposed to an inside surface of the cover with the gap therebetween, is formed with at least one groove in such a manner as to go round the spindle one time along a circumferential direction of the spindle.

2. The spindle unit according to claim 1, wherein the at least one groove is a plurality of grooves.

3. A spindle unit comprising:
a spindle having a tip part to which a mount for mounting a processing tool is connected;
a casing that surrounds at least a part other than the tip part of the spindle and is formed with an air jet port for jetting air toward the spindle in order to form an air bearing; and
a cover mounted to the casing in such a manner as to surround the tip part of the spindle with a gap therebetween,
wherein a region of a side surface of the tip part of the spindle, the region being opposed to an inside surface of the cover with the gap therebetween, is formed with a spiral groove in such a manner as to go round the spindle at least one time along a direction inclined relative to a circumferential direction of the spindle, and
the spindle is rotated such that fluid retained inside the spiral groove is carried toward a mount side.

4. The spindle unit according to claim 3, wherein the spiral groove is formed in such a manner as to go round the spindle at least two times.
